(19) United States
(12) Patent Application Publication
(10) Pub. No.: US 2017/0025573 A1
(43) Pub. Date: Jan. 26, 2017

(54) SEMICONDUCTOR LIGHT EMITTING DEVICE AND SEMICONDUCTOR LIGHT EMITTING DEVICE PACKAGE USING SAME

(71) Applicant: SAMSUNG ELECTRONICS CO., LTD., Suwon-si (KR)

(72) Inventor: Jung Sung KIM, Seoul (KR)

(73) Assignee: SAMSUNG ELECTRONICS CO., LTD., Suwon-si (KR)

(21) Appl. No.: 15/090,707

(22) Filed: Apr. 5, 2016

(30) Foreign Application Priority Data
Jul. 22, 2015 (KR) 10-2015-0103768

(51) Int. Cl. H01L 33/22; H01L 33/60; H01L 33/62; H01L 33/06; H01L 33/50

(52) U.S. Cl. CPC H01L 33/22; H01L 33/06; H01L 33/502; H01L 33/62; H01L 33/60

(57) ABSTRACT

A semiconductor light emitting device may include a substrate including: a first region having a first pattern; and a second region having a second pattern surrounding the first pattern, the second pattern being different from the first pattern; and a light emitting structure disposed on the first and second regions and including: a first conductive semiconductor layer; an active layer; and a second conductive semiconductor layer.

### CROSS-REFERENCE TO RELATED APPLICATION

This application claims priority from Korean Patent Application No. 10-2015-0103768, filed on Jul. 22, 2015, with the Korean Intellectual Property Office, the disclosure of which is incorporated herein by reference in its entirety.

### BACKGROUND

1. Field

Apparatuses consistent with example embodiments relate to a semiconductor light emitting device and a semiconductor light emitting device package using the same.

2. Description of the Related Art

Semiconductor light emitting devices emit light through the recombination of electrons and holes when power is applied thereto, and are commonly used as light sources due to various advantages thereof such as low power consumption, high levels of luminance, compactness, and the like in comparison with other available lighting devices. In particular, after the development of nitride-based semiconductor light emitting devices, the utilization thereof has been greatly expanded and such light emitting devices are commonly employed as light sources in the backlight units of display devices, general lighting devices, the headlights of vehicles, and the like.

As semiconductor light emitting devices have come into widespread use, the utilization thereof is being expanded to the field of high current, high output light sources. As described above, as semiconductor light emitting devices are required in the field of high current and high output light sources, research into improving light emitting efficiency in the high current/high output field has continued. In particular, in order to increase luminance of light emitting devices, a semiconductor light emitting device, a substrate of which has unevenness portions, and a semiconductor light emitting device package using the same, have been proposed.

### SUMMARY

One or more example embodiments may provide a semiconductor light emitting device having improved luminance and a semiconductor light emitting device package using the same.

According to an aspect of an example embodiment, a semiconductor light emitting device may include a substrate and a light emitting structure. The substrate includes a first region having a first pattern and a second region having a second pattern surrounding and different from the first pattern. The light emitting structure includes a first conductive semiconductor layer, an active layer, and a second conductive semiconductor layer, disposed on the first and second regions.

The first pattern may be configured by arranging a plurality of first unevenness portions and the second pattern may be formed by arranging a plurality of second unevenness portions.

The first and second unevenness portions may differ in at least one of shapes, sizes and arrangements.

The second region may be disposed on a periphery of the substrate while having a predetermined width.

According to an aspect of another example embodiment, a semiconductor light emitting device package may include a package body including a first electrode structure and a second electrode structure, a semiconductor light emitting device mounted on the first and second electrode structures, and a wavelength conversion unit covering the semiconductor light emitting device. The semiconductor light emitting device may include a substrate and a light emitting structure. The substrate includes a first region having a first pattern and a second region having a second pattern surrounding and different from the first pattern. The light emitting structure includes a first conductive semiconductor layer, an active layer, and a second conductive semiconductor layer, disposed on the first and second regions.

The first pattern may be formed by arranging a plurality of first unevenness portions and the second pattern may be formed by arranging a plurality of second unevenness portions.

The second region may be disposed on a periphery of the substrate while having a predetermined width.

The predetermined width may be substantially the same as a height of the light emitting device.

The first and second unevenness portions may differ in at least one of shapes, sizes and arrangements.

The semiconductor light emitting device may be bonded to the first and second electrode structures by wires to be mounted thereon.

An aspect ratio of the first unevenness portions may be greater than an aspect ratio of the second unevenness portions.

The first and second unevenness portions may have the same shape, and a size of each of the second unevenness portions may be larger than a size of each of the first unevenness portions.

The semiconductor light emitting device package may further include a reflective unit covering side surfaces of the semiconductor light emitting device, and the semiconductor light emitting device may be mounted on the first and second electrode structures with solder bumps.

An aspect ratio of the second unevenness portions may be greater than an aspect ratio of the first unevenness portions.

The first and second unevenness portions may have the same shape, and a size of each of the second unevenness portions may be larger than a size of each of the second unevenness portions.

According to an aspect of another example embodiment, there is provided a semiconductor light emitting device including: a substrate including: a first region having a first pattern; and a second region having a second pattern surrounding the first pattern, the second pattern being different from the first pattern; and a light emitting structure disposed on the first and second regions and including: a first conductive semiconductor layer; an active layer; and a second conductive semiconductor layer.

The first pattern may include a plurality of first unevenness portions, and the second pattern may include a plurality of second unevenness portions.

The first and second unevenness portions may differ from each other in at least one of shape, size, and arrangement.

The second region may be disposed on a periphery region of the substrate and may have a predetermined width.

The second region may have a predetermined width and is disposed to surround the first region.

The first region may be configured to decrease an orientation angle of light reflected from the substrate, and the second region may be configured to increase the orientation angle of the reflected light.

An aspect ratio of the first unevenness portions may be different from an aspect ratio of the second unevenness portions.

The predetermined width may be substantially the same as a thickness of the semiconductor light emitting device.

According to an aspect of another example embodiment, there is provided a semiconductor light emitting device package including: a package body including: a first electrode structure; and a second electrode structure; a semiconductor light emitting device mounted on the first and second electrode structures; and a wavelength conversion unit covering the semiconductor light emitting device, wherein the semiconductor light emitting device may include: a substrate; and a light emitting structure including: a first conductive semiconductor layer; an active layer; and a second conductive semiconductor layer, wherein the substrate may include: a first region having a first pattern; and a second region having a second pattern surrounding the first pattern, the second pattern being different from the first pattern, and wherein the light emitting structure is disposed on the first and second regions.

The first pattern may include a plurality of first unevenness portions, and the second pattern may include a plurality of second unevenness portions.

The second region may be disposed on a periphery region of the substrate and may have a predetermined width.

The semiconductor light emitting device package may further include wires configured to bond the semiconductor light emitting device to the first and second electrode structures.

An aspect ratio of the first unevenness portions may be different from an aspect ratio of the second unevenness portions.

The first and second unevenness portions have the same shape, and a size of each of the second unevenness portions may be different from a size of each of the first unevenness portions.

The semiconductor light emitting device package may further include a reflective unit covering side surfaces of the semiconductor light emitting device, wherein the semiconductor light emitting device may be mounted on the first and second electrode structures with solder bumps.

According to an aspect of another example embodiment, there is provided a semiconductor light emitting device including: a substrate including: a first region having a first pattern; and a second region surrounding the first region and having a second pattern different from the first pattern; and a light emitting structure disposed on the first and second regions, wherein the first pattern may include a plurality of first unevenness portions, and the second pattern comprises a plurality of second unevenness portions, and wherein the first and second unevenness portions differ from each other in at least one of shape, size, and arrangement.

### BRIEF DESCRIPTION OF DRAWINGS

The above and other aspects, features and other advantages of the disclosure will be more clearly understood from the following detailed description taken in conjunction with the accompanying drawings, in which:

FIG. 1 is a schematic cross-sectional view of a semiconductor light emitting device package according to an example embodiment;

FIG. 2 is a schematic cross-sectional view illustrating a semiconductor light emitting device of FIG. 1;

FIG. 3A is a schematic plan view of a substrate of FIG. 2;

FIG. 3B is a cross-sectional view taken along line a-b of FIG. 3A;

FIGS. 4A through 6B are modifications of the substrate of FIG. 2;

FIG. 7 is a schematic cross-sectional view of a semiconductor light emitting device package according to an example embodiment;

FIG. 8 is a schematic cross-sectional view illustrating a semiconductor light emitting device of FIG. 7;

FIG. 9 is a schematic cross-sectional view of a backlight unit according to an example embodiment; and

FIG. 10 is a schematic cross-sectional view of a backlight unit according to an example embodiment.

### DETAILED DESCRIPTION

Various example embodiments will now be described more fully with reference to the accompanying drawings in which some embodiments are shown. The present disclosure may, however, be embodied in different forms and should not be construed as limited to the embodiments set forth herein. Rather, the example embodiments are provided so that this disclosure is thorough and complete and fully conveys the present disclosure to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, when an example embodiment can be implemented differently, functions or operations described in a particular block may occur in a different way from a flow described in the flowchart. For example, two consecutive blocks may be performed simultaneously, or the blocks may be performed in reverse according to related functions or operations.

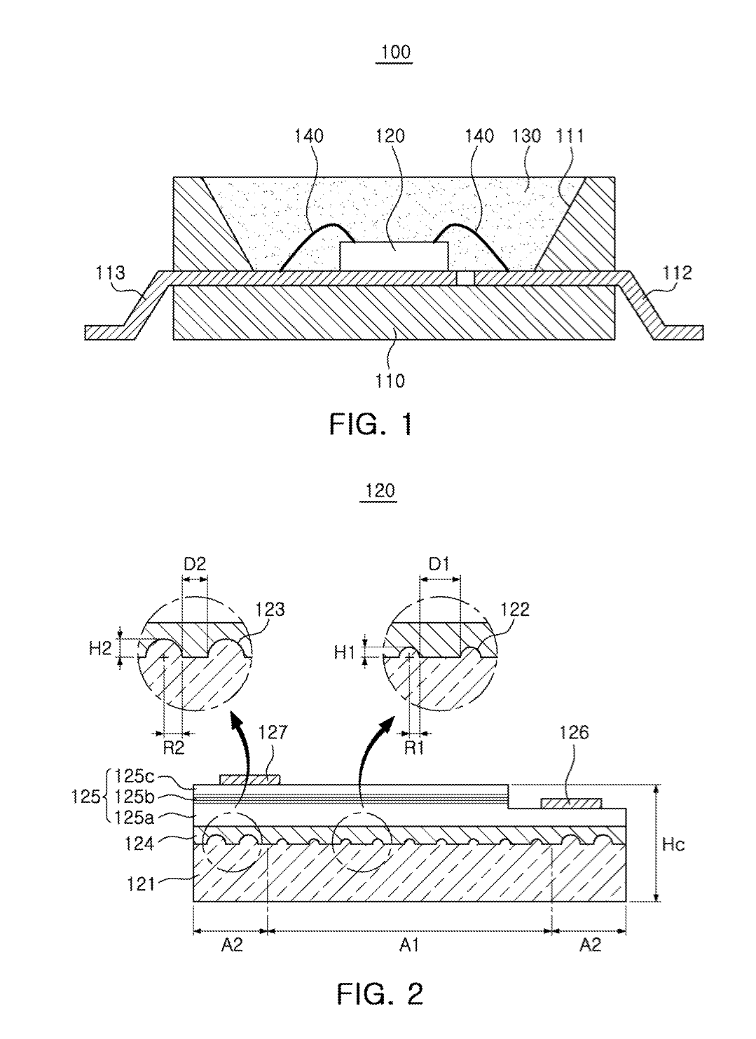

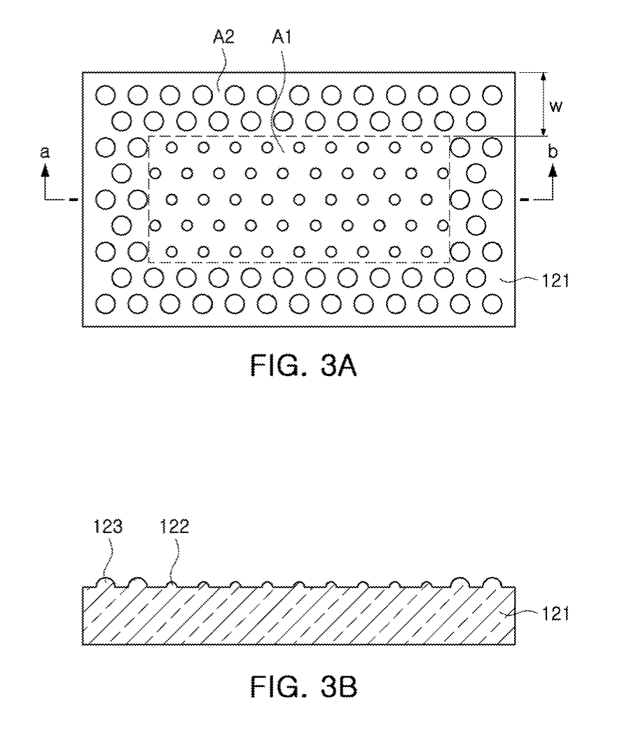

FIG. 1 is a schematic cross-sectional view of a semiconductor light emitting device package 100 according to an example embodiment. FIG. 2 is a schematic cross-sectional view illustrating a semiconductor light emitting device 100 of FIG. 1. FIG. 3 is a schematic plan view of a substrate 121 of FIG. 2.

Referring to FIG. 1, a semiconductor light emitting device package 100 according to an example embodiment may include a package body 110 having a first lead frame 112 and a second lead frame 113 and a semiconductor light emitting device 120 mounted on the first and second lead frames 112 and 113. The semiconductor light emitting device package 100 may also include a sealing portion 130 covering the semiconductor light emitting device 120. The sealing portion 130 may contain a wavelength converting material.

The package body 110 may be formed by molding insulating resin in a region of the first and second lead frames 112 and 113. In a region of the package body 110, a recess portion 111 having sloping side surfaces may be included, and a portion of the first and second lead frames 112 and 113 may be exposed to a bottom surface of the recess portion 111. The first and second lead frames 112 and 113 exposed to the bottom surface of the recess portion 111 may be bonded to the semiconductor light emitting device 120 by wires 140.

The first and second lead frames 112 and 113 may be an electrode structure for applying power to the semiconductor light emitting device 120. The first and second lead frames 112 and 113 are formed on the basis of a base substrate, and may be disposed to be spaced apart from each other on the package body 110. Regions of the first and second lead frames 112 and 113 on which the semiconductor light emitting device 120 is mounted may have a flat upper surface such that the semiconductor light emitting device 120 may be readily mounted thereon. The base substrate may be formed by using a metal having excellent electrical conductivity, such as copper (Cu), a Cu alloy or a phosphor-bronze alloy, but is not limited thereto.

The sealing portion 130 may be disposed in the recess portion 111 of the package body 110 to cover the semiconductor light emitting device 120. The sealing portion 130 may be formed using a transparent liquid resin, such as a resin selected from a group consisting of silicone resin, epoxy resin, acrylic resin, polymethyl methacrylate (PMMA) resin, mixtures thereof and compounds thereof, and may be disposed to fill the recess portion 111 of the package body 110.

The sealing portion 130 may contain a wavelength converting material, such as a phosphor or a quantum dot. As for the phosphor, a garnet-based phosphor (YAG, TAG, LuAG), a silicate-based phosphor, a nitride-based phosphor, a sulfide-based phosphor, an oxide-based phosphor, or the like may be used. The sealing portion 130 may be formed to include a single kind of phosphor or may be formed to include multiple kinds of phosphors mixed at a predetermined ratio.

Referring to FIG. 2, the semiconductor light emitting device 120 may include a substrate 121 having a first region A1 and a second region A2, a light emitting structure 125 disposed on the substrate 121, and a first electrode 126 and a second electrode 127 electrically connected to the light emitting structure 125.

The substrate 121 may be provided as a semiconductor growth substrate. The substrate 121 may be formed by using an insulating material, a conducting material and a semiconductor material, such as sapphire, SiC, MgAl₂O₄, MgO, LiAlO₂, LiGaO₂, and GaN. In the example embodiment, the sapphire is a crystal having Hexa-Rhombo R3c symmetry, of which lattice constants in c-axis and a-axis directions are 13.001 Å and 4.758 Å, respectively. The sapphire crystal has a C plane (0001), an A plane (11-20), an R plane (1-102), and the like. In this case, a nitride thin film may be relatively easily formed on the C plane, and because the sapphire crystal is stable at relatively high temperatures, it is commonly used as a material for a nitride growth substrate. For instance, according to this example embodiment, the substrate 121 may be a light transmitting substrate.

One surface of the substrate 121, i.e., a surface provided as a growth surface for semiconductor layers forming the light emitting structure 125, may have a pattern including a plurality of unevenness portions. By incorporating the plurality of unevenness portions, crystallizability and luminous efficiency of the semiconductor layers configuring the light emitting structure 125 may be improved. Such a pattern may be constructed by a plurality of unevenness portions forming rows and columns. The pattern may be formed on opposing surfaces of the substrate 121 according to example embodiments of the present disclosure.

The pattern may also be arranged in a manner in which multiple groups of patterns varying in at least one of shapes, sizes and arrangements are distributed in divided/different regions of the substrate 121. An example embodiment of the present disclosure illustrates a case in which the first and second regions A1 and A2 having the different shapes of the first and second patterns are arranged on the substrate 121 and the first and second patterns have a plurality of first unevenness portions 122 and a plurality of second unevenness portions 123 having different sizes and disposed thereon, but is not limited thereto. For example, three or more patterns may be distributed in divided regions.

The first region A1 may be disposed in a central region of the substrate 121, and the second region A2 may be disposed while having a width W in a periphery of the substrate 121 (see FIG. 3A). The shapes and sizes of elements in the drawings may also be exaggerated to look different from each other in size, but the height Hc of the semiconductor light emitting device 120 may be substantially the same as the width W of the second region A2. As such, when the height Hc of the semiconductor light emitting device 120 becomes identical to the width W of the second region A2, light extraction efficiency may be further improved.

Cross-sections of the first and second unevenness portions 122 and 123 perpendicular to one surface of the substrate 121 may be semi-circular, semi-ovalar or polygonal. Each of the cross-sections may also be a shape in which a semi-circle and a polygon are combined, and the polygon may be trapezoidal, quadrangular or triangular. That is, the shape of the first and second unevenness portions 122 and 123 is not particularly limited. Further, the first and second unevenness portions 122 and 123 may be three-dimensional shapes having a hemispherical, conic or polypyramidal appearance.

The first and second unevenness portions 122 and 123 may be different in shapes. That is, the first and second unevenness portions 122 and 123 may have different cross-sections. For example, the first unevenness portions 122 may be hemispherical and the second unevenness portions 123 may be polypyramidal.

In addition, the first and second unevenness portions 122 and 123 may have the same shape and different sizes. For example, as shown in FIG. 2, the cross-sections of the first and second unevenness portions 122 and 123 have the same hemispherical shape and different radii H1 and H2.

Further, the first and second unevenness portions 122 and 123 may have the same shape and size and different arrangements. For example, varying a gap D1 between the first unevenness portions 122 and a gap D2 between the second unevenness portions 123 may allow the patterns disposed in the first and second regions A1 and A2 to be arranged differently from each other. That is, respective densities of the first and second unevenness portions 122 and 123 may be different from each other.

As such, varying at least one of the shape, size and arrangement (including densities) of the patterns disposed in the first and second regions A1 and A2 may control an orientation of light emitted by the semiconductor light emitting device 120 to increase the luminance of the semiconductor light emitting device package 100. This will be described in detail hereinafter.

The luminance of the semiconductor light emitting device package 100 may be affected by the light extraction efficiency of the semiconductor light emitting device 120 and color conversion efficiency of a wavelength conversion unit. Therefore, in order to increase the luminance of the semiconductor light emitting device package 100, an amount of light emitted by the semiconductor light emitting device 120 should be increased and a loss of light in a color conversion process of the wavelength conversion unit should be reduced. For instance, because white light is obtained through color conversion into white while blue light passes through the wavelength conversion unit, efficiency of transformation into white light should be improved while increasing an amount of the blue light to increase the luminance of the white light.

As illustrated in FIGS. 1 and 2, an epi-up chip type of semiconductor light emitting device 120 allows a portion of light emitted by an active layer 125b to be reflected from the substrate 121 and released through the semiconductor layer forming the light emitting structure 125. In this process, a portion of the light is absorbed into the semiconductor layer to reduce light extraction efficiency. Resultantly, light reflected from the substrate 121 is released outside the semiconductor light emitting device 120 at a relatively shortest distance and thus the light extraction efficiency of the epi-up chip may be improved.

According to an example embodiment, unevenness portions may be disposed in a predetermined region on the periphery of the substrate 121 to increase an orientation angle of reflected light so that the reflected light may be rapidly released to the side surfaces of the semiconductor light emitting device 120. In the first region A1 disposed in the center of the substrate 121, the unevenness portions for reducing the orientation angle of reflected light are disposed because a distance where light is emitted to a top surface of the semiconductor light emitting device 120 is generally shorter than a distance where light is emitted to the side surfaces of the semiconductor light emitting device 120.

For example, the epi-up chip has unevenness portions disposed in the first region A1 of the substrate 121 to decrease an orientation angle of reflected light and unevenness portions disposed in the second region A2 of the substrate 121 to increase an orientation angle of reflected light, so that light emitted by the active layer 125b may be released outside the semiconductor light emitting device 120 at a shortest distance. Thus, the light extraction efficiency of the semiconductor light emitting device 120 may be improved.

As such, the orientation angle of reflected light may be increased by increasing the size of the unevenness portions, forming the unevenness portions to have a semi-spherical shape, decreasing an aspect ratio of the unevenness portions, or widening a gap between the unevenness portions. On the other hand, the orientation angle of reflected light may be decreased by decreasing the size of the unevenness portions, forming the unevenness portions to have a shape close to a pyramid or column, increasing the aspect ratio of the unevenness portions, or narrowing the gap between the unevenness portions.

FIGS. 3A through 5B are examples in which the unevenness portions are disposed such that an orientation angle of light reflected from the second region A2 is greater than an orientation angle of light reflected from the first region A1.

FIG. 3A is a plan view of the substrate 121, and FIG. 3B is a cross-sectional view taken along line a-b of the substrate 121 of FIG. 3A. The first unevenness portions 122 are disposed in the first region A1 in a central portion of the substrate 121, and the second unevenness portions 123 are disposed in the second region A2 on the periphery of the substrate 121 surrounding the first region A1. Each size of the second unevenness portions 123 may be larger than that of the first unevenness portions 122.

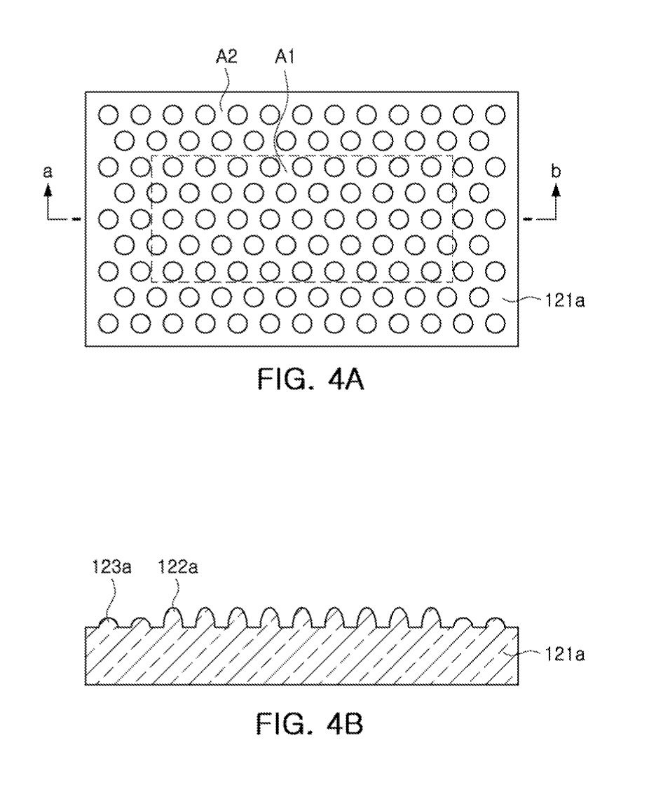

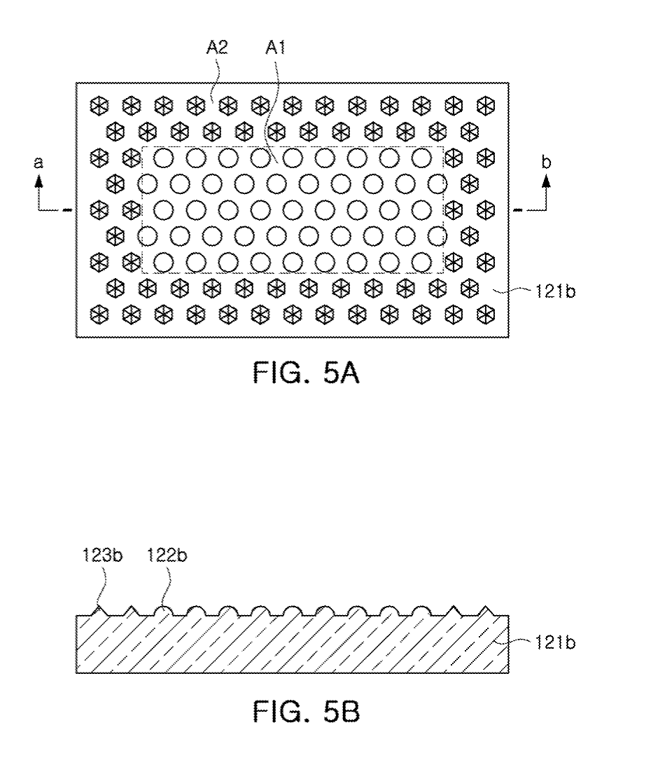

FIGS. 4A through 5B are modifications of FIGS. 3A and 3B.

FIG. 4A is a plan view of a substrate 121a, and FIG. 4B is a cross-sectional view taken along line a-b of the substrate 121a of FIG. 4A. As compared to the example embodiments described above, FIGS. 4A and 4B differ in that unevenness portions are disposed such that an aspect ratio of a plurality of first unevenness portions 122a disposed in a first region A1 is greater than an aspect ratio of a plurality of second unevenness portions 123a disposed in the second region A2.

FIG. 5A is a plan view of a substrate 121b, and FIG. 5B is a cross-sectional view taken along line a-b of the substrate 121b of FIG. 5A. As compared to the example embodiments described above, FIGS. 5A and 5B differ in that a size of each of a plurality of first unevenness portions 122b disposed in the first region A1 is greater than a size of each of a plurality of second unevenness portions 123b having a hexagonal pyramid shape disposed in the second region A2.

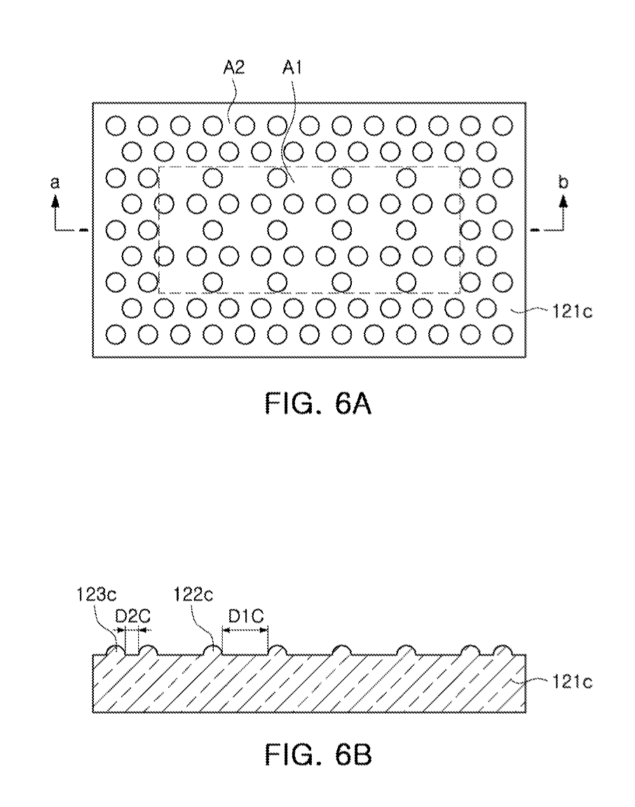

FIGS. 6A and 6B are examples in which unevenness portions are disposed such that an orientation angle of light reflected from the first region A1 is greater than an orientation angle of light reflected from the second region A2. Such a configuration is suitable for a structure in which the semiconductor light emitting device is mounted on the substrate in a flip chip manner. In this regard, the configuration will be described in more detail in another example embodiment.

FIG. 6A is a plan view of a substrate 121c, and FIG. 6B is a cross-sectional view taken along line a-b of the substrate 121c of FIG. 6A. FIGS. 6A and 6B differ in that unevenness portions 122c disposed in the first region A1 and unevenness portions 123c disposed in the second region A2 have the same shape and size and the unevenness portions are disposed such that a gap (D2C) between the second unevenness portions 123c is narrower than a gap (D1C) between the first unevenness portions 122c. That is, a density of the unevenness portions 123c is greater than that of the unevenness portions 122c.

The substrate 121 may include the following semiconductor layers and electrodes disposed thereon.

Referring to FIG. 2, the substrate 121 may further include a buffer layer 124 for improving crystallinity of the semiconductor layers configuring the light emitting structure 125. The buffer layer 124 may include, for example, aluminum gallium nitride (AlₓGa₁₋ₓN) formed at a relatively low temperature without doping. According to an example embodiment of the present disclosure, a portion of the substrate 121 may be removed.

The light emitting structure 125 may include a first conductive semiconductor layer 125a, the active layer 125b, and a second conductive semiconductor layer 125c. The first and second conductive semiconductor layers 125a and 125c may include semiconductors doped with n- and p-type impurities, respectively, but are not limited thereto. For example, the first and second conductive semiconductor layers may include p- and n-type semiconductors, respectively. The first and second conductive semiconductor layers 125a and 125c may include a nitride semiconductor, for example, a material having a composition of AlₓIn_{y}Ga_{1-x-y}N (0≦x≦1, 0≦y≦1, 0≦x+y≦1). Each of the first and second conductive semiconductor layers may include a single layer but may include a plurality of layers having different properties, for example, different doping densities and compositions. The first and second conductive semiconductor layers 125a and 125c may be formed by employing an AlInGaP- or AlInGaAs-based semiconductor as well as a nitride semiconductor. According to an example embodiment, the first conductive semiconductor layer 125a may be, for example, an n-type gallium nitride (n-GaN) layer doped with silicon (Si) or carbon (C) and the second conductive semiconductor layer 125c may be, for example, a p-type gallium nitride (p-GaN) layer doped with magnesium (Mg) or zinc (Zn).

The active layer 125b disposed between the first and second conductive semiconductor layers 125a and 125c emits light having a predetermined energy by a recombination of electrons and holes, and may be a layer containing a single material, such as indium gallium nitride (InGaN). In addition, the active layer may be formed by employing a single quantum well (SQW) structure or a multi-quantum well (MQW) structure, in which a quantum barrier layer and a quantum well layer are alternately arranged with each other, for example, a gallium nitride (GaN)/indium gallium nitride (InGaN) structure in the case of a nitride semiconductor. When the active layer 125b contains indium gallium nitride (InGaN), an increase in an indium (In) content may reduce crystal defects caused by lattice mismatching and may increase internal quantum efficiency of the semiconductor light emitting device 120. According to the content of indium (In) in the active layer 125b, a light emitting wavelength may be adjusted.

The first and second electrodes 126 and 127 may be disposed on the first and second conductive semiconductor layers 125a and 125c, respectively, to be electrically connected to each other. The first and second electrodes 126 and 127 may include a single- or multi-layer structure of conductive material. For example, the first and second electrodes 126 and 127 may contain a material, such as gold (Au), silver (Ag), copper (Cu), zinc (Zn), aluminum (Al), indium (In), titanium (Ti), silicon (Si), germanium (Ge), tin (Sn), magnesium (Mg), tantalum (Ta), chrome (Cr), tungsten (W), ruthenium (Ru), rhodium (Rh), iridium (Ir), nickel (Ni), palladium (Pd), platinum (Pt), or the like, or at least one alloy thereof. According to an example embodiment, at least one of the first and second electrodes 126 and 127 may be a transparent electrode and may include, for example, indium tin oxide (ITO), aluminium zinc oxide (AZO), indium zinc oxide (IZO), zinc oxide (ZnO), ZnO:Ga (GZO), indium oxide (In₂O₃), tin oxide (SnO₂), cadmium oxide (CdO), cadmium tin oxide (CdSnO₄), or gallium oxide (Ga₂O₃).

The location and/or shape of the first and second electrodes 126 and 127 illustrated in FIG. 2 are merely examples and may change according to the design intent. According to an example embodiment, an ohmic electrode layer may be further disposed on the second conductive semiconductor layer 125c. The ohmic electrode layer may include p-GaN containing a high-concentration p-type impurity. Alternatively, the ohmic electrode layer may be formed of a metal or a transparent conductive oxide.

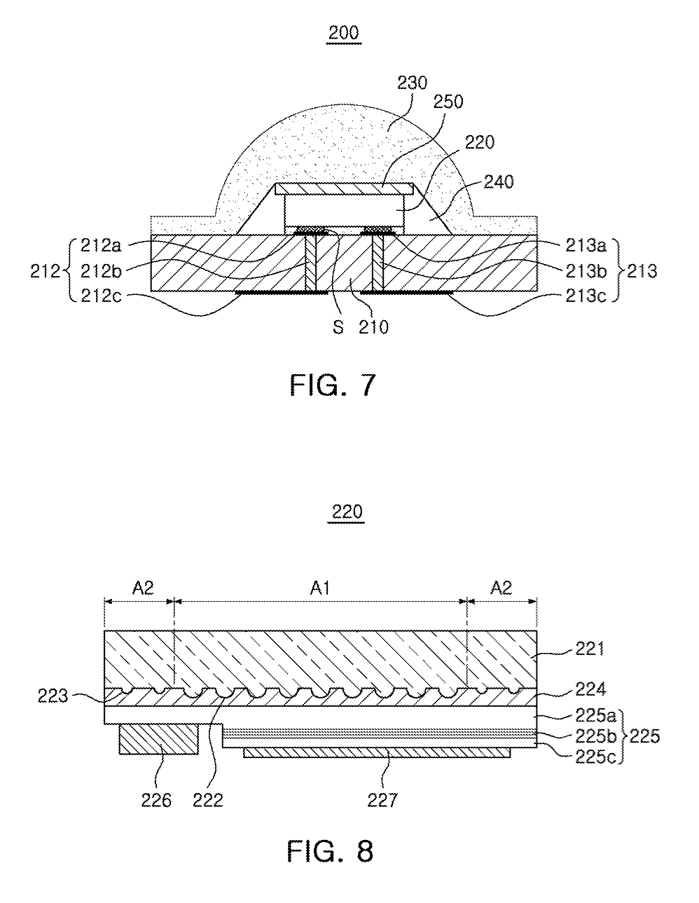

FIG. 7 is a schematic cross-sectional view of a semiconductor light emitting device package 200 according to an example embodiment, and FIG. 8 is a schematic cross-sectional view illustrating the semiconductor light emitting device 220 of FIG. 7. Redundant descriptions with FIGS. 1 and 2 will be omitted herein.

Referring to FIG. 7, the semiconductor light emitting device package 200 includes a package body 210 having a first electrode structure 212 and a second electrode structure 213 and a semiconductor light emitting device 220 mounted on the first and second electrode structures 212 and 213. In addition, a wavelength conversion unit 250 may be disposed on the semiconductor light emitting device 220. The semiconductor light emitting device package may also include a sealing portion 230 covering the wavelength conversion unit 250. A reflective unit 240 reflecting light may be disposed on side surfaces of the semiconductor light emitting device 220.

As compared to the example embodiments described above, the example embodiment with reference to FIG. 7 differs in that the semiconductor light emitting device 220 is mounted on the package body 210 in a flip chip manner and the electrode structure is configured of a via electrode, and in that wavelength converting material is dispersed in the separate wavelength conversion unit 250.

The package body 210 may have the first and second electrode structures 212 and 213. The first and second electrode structures 212 and 213 may include a first via electrode 212b and a second via electrode 213b formed in a thickness direction thereof to pass through a first surface of the package body 210 on which the semiconductor light emitting device 220 is mounted and a second surface opposing the first surface. First bonding pads 212a and 212c and second bonding pads 213a and 213c are provided on the first and second surfaces of the package body 210, to which opposing ends of the first and second via electrodes 212b and 213b are exposed, respectively. Thus, the first and second surfaces of the package body 210 may be electrically connected to each other.

Referring to FIG. 8, the semiconductor light emitting device 220 may include a substrate 221 having a first region A1 and a second region A2, a light emitting structure 225 disposed on the substrate 221, and a first electrode 226 and a second electrode 227 electrically connected to the light emitting structure 225.

As compared to the example embodiments described above, the example embodiment with reference to FIG. 8 differs in that a pattern is arranged in the second region A2 to further decrease an orientation angle of light emitted by an active layer 225b. For example, a plurality of second unevenness portions 223 are disposed in a manner further decreasing an orientation angle of reflected light. Accordingly, the second unevenness portions 223 may be smaller and have a greater aspect ratio than those of the first unevenness portions 222, and may be more hemispherical in shape as compared to the first unevenness portions 222. Further, the second unevenness portions 223 may be arranged such that a gap between the second unevenness portions 223 may be reduced.

A buffer layer 224 may be further disposed on the substrate 221 to improve crystallinity of semiconductor layers forming the light emitting structure 225. The light emitting structure 225 may include a first conductive semiconductor layer 225a, an active layer 225b and a second conductive semiconductor layer 225c. The first and second electrodes 226 and 227 may be electrically connected to the first and second bonding pads 212a and 213a of the package body 210, respectively, through a conductive bonding material S (FIG. 7), for example, a solder bump containing Sn.

The wavelength conversion unit 250 may be disposed to cover the semiconductor light emitting device 220 and at least a portion of the reflective unit 240. The wavelength conversion unit 250 may be disposed in the form of a film in which a wavelength converting material is dispersed in a light transmitting material. The wavelength conversion unit 250 may have a film shape with a substantially uniform thickness.

The flip chip-type semiconductor light emitting device 220 as shown in FIGS. 7 and 8 allows light emitted by the active layer 225b to be reflected from a reflecting layer, such as the second electrode 227 disposed on a bottom of the light emitting structure 225, and to then be released through the substrate 221. Thus, light moving toward the side surfaces of the semiconductor light emitting device 220 is reflected from the reflective unit 240 disposed on the side surfaces and then released through the substrate 221. Because the reflective unit 240 has a relatively high reflectivity but not 100%, a portion of light is absorbed into the reflective unit 240. Also, a portion of light reflected from the reflective unit 240 is absorbed into the semiconductor layer while passing therethrough.

Therefore, in the case of the flip chip structure, unevenness portions may be disposed in the second region A2 on a periphery of the substrate 221 to further decrease an orientation angle of reflected light, so that light reflected from the second electrode 227 may be emitted to an upper portion of the substrate 221 prior to re-reflection from the reflective unit 240. As a result, a reduction of light absorbed into the reflective unit 240 may increase an amount of light emitted to the outside of the semiconductor light emitting device 220. For example, an amount of light externally emitted may be increased by further reducing the size of unevenness portions disposed in the second region A2, increasing an aspect ratio of the unevenness portions, allowing the unevenness portions to have a substantially hemispherical shape, or further decreasing a gap between the unevenness portions.

An improvement of light extraction efficiency of the semiconductor light emitting device package 200 according to an example embodiment is described with a detailed experimental example.

A comparative example in which the same pattern of hemispherical unevenness portions is formed on the entirety of a front surface of the substrate is compared with an example embodiment of the present disclosure in which different patterns of hemispherical unevenness portions are formed in the first and second regions of the substrate 121 and 221. Other conditions except the substrate pattern are the same.

The hemispherical unevenness portions of the comparative example had a radius of 1 μm, a height of 1 μm, a gap therebetween of 2.5 μm, respectively, and was disposed on 58% of a substrate area.

According to an example embodiment of the present disclosure, unevenness portions having a radius of 1.25 μm, a height of 1.5 μm, and a gap therebetween of 3.125 μm was disposed in the first region of the substrate, and unevenness portions having a radius of 0.5 μm, a height of 1.5 μm, and a gap therebetween of 1.25 μm was disposed in the second region of the substrate. An area of the unevenness portions disposed in the first and second regions was about 58% in the same as the comparative example.

Applying the same amount of power to the same package under such conditions resulted in, in the comparative example, a rate of light (a ratio of light distribution to a top surface) toward the top surface of the semiconductor light emitting device package being 60.72% and the luminance of white light being 32.191 lm. Meanwhile, in the example embodiment, the ratio of light distribution to the top surface was about 62.75% (increased by 2%) and the luminance of white light was about 32.244 lm (increased by 0.2%). Thus, in the case of the example embodiment, it could be confirmed that the luminance of white light was increased, as compared to the comparative example.

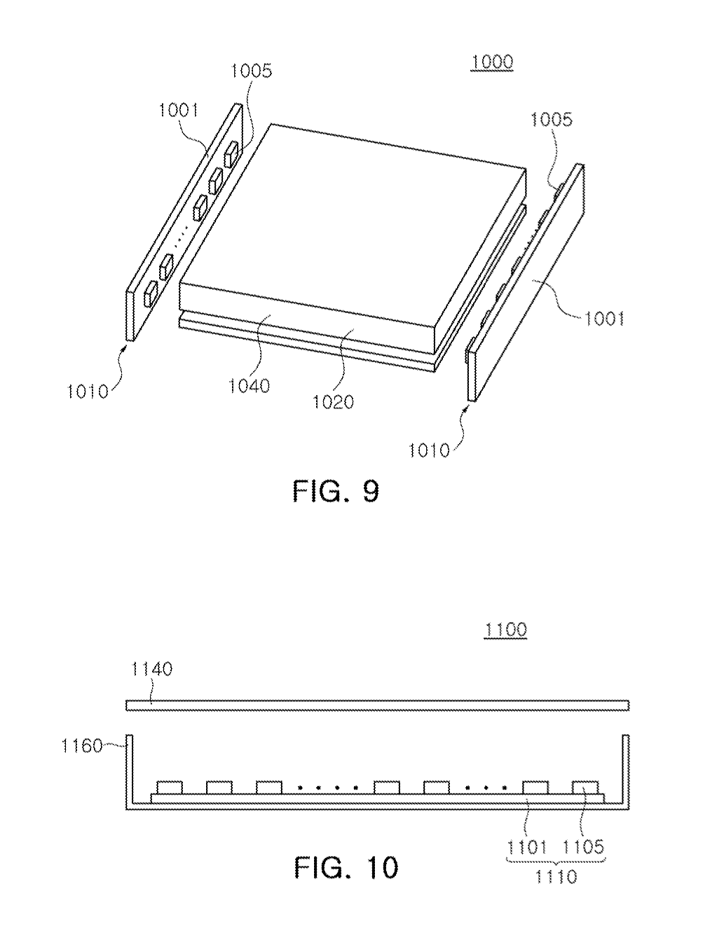

FIG. 9 is a schematic cross-sectional view of a backlight unit according to an example embodiment of the present disclosure.

Referring to FIG. 9, a backlight unit 1000 may include a light guide plate 1040 and light source modules 1010 provided on opposing sides thereof. In addition, the backlight unit 1000 may further include a reflecting plate 1020 disposed below the light guide plate 1040. The backlight unit 1000 according to the example embodiment of the present disclosure may be an edge type backlight unit.

According to example embodiments of the present disclosure, the light guide plate 1040 may only be provided on one side surface of the light source modules 1010 or additionally on other side surfaces thereof. The light source modules 1010 may include a printed circuit board (PCB) 1001 and a plurality of light emitting devices 1005 mounted on a surface of the PCB 1001. Each of the light emitting devices 1005 may include the semiconductor light emitting device package 100 or 200 illustrated respectively in FIGS. 1 and 7.

FIG. 10 is a schematic cross-sectional view of a backlight unit according to an example embodiment of the present disclosure.

Referring to FIG. 10, a backlight unit 1100 may include a light diffusing plate 1140 and a light source module 1110 arranged therebelow. In addition, the backlight unit 1100 may further include a bottom case 1160 disposed below the light diffusing plate 1140 to receive the light source module 1110 therein. The backlight unit 1100 according to the example embodiment of the present disclosure may be a direct type backlight unit.

The light source module 1110 may include a PCB 1101 and a plurality of light emitting devices 1105 mounted on a surface of the PCB 1101, and each of the light emitting devices 1105 may include the semiconductor light emitting device package 100 or 200 illustrated respectively in FIGS. 1 and 7.

As set forth above, according to an example embodiment of the present disclosure, a semiconductor light emitting device and a semiconductor light emitting device package using the same may have improved luminance by arranging different patterns on substrate regions.

While example embodiments have been shown and described above, it will be apparent to those skilled in the art that modifications and variations could be made therein without departing from the scope of the inventive concept as defined by the following claims.

What is claimed is:

1. A semiconductor light emitting device comprising:
a substrate comprising:
a first region having a first pattern; and
a second region having a second pattern surrounding the first pattern, the second pattern being different from the first pattern; and
a light emitting structure disposed on the first and second regions and comprising:
a first conductive semiconductor layer;
an active layer; and
a second conductive semiconductor layer.

2. The semiconductor light emitting device of claim 1, wherein the first pattern comprises a plurality of first unevenness portions, and the second pattern comprises a plurality of second unevenness portions.

3. The semiconductor light emitting device of claim 2, wherein the first and second unevenness portions differ from each other in at least one of shape, size, and arrangement.

4. The semiconductor light emitting device of claim 1, wherein the second region is disposed on a periphery region of the substrate and has a predetermined width.

5. The semiconductor light emitting device of claim 1, wherein the second region has a predetermined width and is disposed to surround the first region.

6. The semiconductor light emitting device of claim 1, wherein the first region is configured to decrease an orientation angle of light reflected from the substrate, and
wherein the second region is configured to increase the orientation angle of the reflected light.

7. The semiconductor light emitting device of claim 2, wherein an aspect ratio of the first unevenness portions is different from an aspect ratio of the second unevenness portions.

8. The semiconductor light emitting device of claim 4, wherein the predetermined width is substantially the same as a thickness of the semiconductor light emitting device.

9. A semiconductor light emitting device package comprising:
a package body comprising:
a first electrode structure; and
a second electrode structure;
a semiconductor light emitting device mounted on the first and second electrode structures; and
a wavelength conversion unit covering the semiconductor light emitting device,
wherein the semiconductor light emitting device comprises:
a substrate; and
a light emitting structure comprising:
a first conductive semiconductor layer;
an active layer; and
a second conductive semiconductor layer,
wherein the substrate comprises:
a first region having a first pattern; and
a second region having a second pattern surrounding the first pattern, the second pattern being different from the first pattern, and
wherein the light emitting structure is disposed on the first and second regions.

10. The semiconductor light emitting device package of claim 9, wherein the first pattern comprises a plurality of first unevenness portions, and
wherein the second pattern comprises a plurality of second unevenness portions.

11. The semiconductor light emitting device package of claim 9, wherein the second region is disposed on a periphery region of the substrate and has a predetermined width.

12. The semiconductor light emitting device package of claim 11, wherein the predetermined width is substantially the same as a height of the light emitting device.

13. The semiconductor light emitting device package of claim 10, wherein the first and second unevenness portions differ from each other in at least one of shape, size and arrangement.

14. The semiconductor light emitting device package of claim 13 further comprising wires configured to bond the semiconductor light emitting device to the first and second electrode structures.

15. The semiconductor light emitting device package of claim 14, wherein an aspect ratio of the first unevenness portions is different from an aspect ratio of the second unevenness portions.

16. The semiconductor light emitting device package of claim 14, wherein the first and second unevenness portions have the same shape, and
wherein a size of each of the second unevenness portions is different from a size of each of the first unevenness portions.

17. The semiconductor light emitting device package of claim 13, further comprising a reflective unit covering side surfaces of the semiconductor light emitting device,
wherein the semiconductor light emitting device is mounted on the first and second electrode structures with solder bumps.

18. A semiconductor light emitting device comprising:
a substrate comprising:
a first region having a first pattern; and
a second region surrounding the first region and having a second pattern different from the first pattern; and
a light emitting structure disposed on the first and second regions,
wherein the first pattern comprises a plurality of first unevenness portions, and the second pattern comprises a plurality of second unevenness portions, and
wherein the first and second unevenness portions differ from each other in at least one of shape, size, and arrangement.

19. The semiconductor light emitting device of claim 18, wherein an aspect ratio of the first unevenness portions is different from an aspect ratio of the second unevenness portions.

20. The semiconductor light emitting device of claim 18, wherein the predetermined width is substantially the same as a thickness of the semiconductor light emitting device.
